(19) United States
(12) Patent Application Publication
(10) Pub. No.: US 2008/0122012 A1
(43) Pub. Date: May 29, 2008

(54) SEMICONDUCTOR DEVICE AND METHOD OF MANUFACTURING THE SAME

(75) Inventor: Jota FUKUHARA, Yokkaichi-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/771,518

(22) Filed: Jun. 29, 2007

(30) Foreign Application Priority Data
Jun. 30, 2006 (JP) 2006-181552

(51) Int. Cl. H01L 29/78; H01L 21/762

(52) U.S. Cl. 257/397; 438/437; 257/E21.546; 257/E29.255

(57) ABSTRACT

A method of manufacturing a semiconductor device, includes forming a gate insulating film on a semiconductor substrate; forming a polycrystalline silicon film on the gate insulating film; forming a silicon nitride film on the polycrystalline silicon film; anisotropically etching the silicon nitride film, the polycrystalline silicon film, the gate insulating film and the semiconductor substrate so as to form a trench; forming a first silicon oxide film on a surface of the trench by thermal CVD process; forming a second silicon oxide film on the first silicon oxide film, the second silicon oxide film including a silicon oxide film (SiOx: x≦2) or a silicon oxide film containing 1×10¹³/cm³ or more metal atoms or carbon atoms; and executing plasma treatment on the second silicon oxide film in an oxidating atmosphere.

### CROSS-REFERENCE TO RELATED APPLICATIONS

This application is based upon and claims the benefit of priority from the prior Japanese Patent Application No. 2006-181552, filed on, Jun. 30, 2006 the entire contents of which are incorporated herein by reference.

### FIELD

The present disclosure is directed to a semiconductor device having a trench filled with an insulating film for element isolation defined on a semiconductor substrate and a method of manufacturing such semiconductor device.

### BACKGROUND

Some non-volatile memory devices such as a NAND flash memory device isolate elements of the device with an STI (Shallow Trench Isolation) structure. The STI structure is formed by the following process flow, for example. A gate insulating film, a polycrystalline silicon film, and a silicon nitride film are deposited on the silicon substrate. Next, a resist is patterned by photolithography process to define an opening on the laminated films by RIE (Reactive Ion Etching) process and a trench is defined on the silicon substrate via the opening. Then, the trench defined in the silicon substrate is filled with an insulating film to obtain the STI structure.

The conventional method generally employed in filling the trench of the silicon substrate has been the use of HDP (High Density Plasma) film as the insulating film to fill the trench. However, further integration of design rules calls for narrower width of the trenches formed in the silicon substrate. The lack of gap-fill capability of the HDP film provided grounds for occurrences of voids in gap-fill, which has lead to problems such as caving in forming device elements.

To eliminate such problems, a technology referred to as ALD (Atomic Layer Deposition) has been conceived in which the trenches are filled with insulating films without occurrence of voids. The details of ALD is described for instance, in JP 2003-7700 A and D. Hausmann et al, “Rapid Vapor Deposition of Highly Conformal Silica Nanolaminates”, Science, 11, Oct. 2002, vol 298, p 402-406.

ALD adsorbs gases such as TMA (trimethylaluminum: Al(CH₃)₃) on the surface of the silicon substrates having the above described trenches formed therein and thereafter forms the insulating film by flowing gas such as silanol based gas such as (Si(OCH₃)₃OH).

However, in employing ALD, the precursor for forming the insulating film causes Al (aluminum) itself and silicon-rich films to remain in the insulating film formed on the silicon substrate surface. That is, when ALD is employed in the manufacture of non-volatile semiconductor devices such as flash memory device, where a gate electrode is prefabricated, aluminum and silicon rich film exist on the surface of the gate insulating film. Thus, when voltage is applied to the gate material, a leak current occurs between the silicon substrate and the polycrystalline silicon film, constituting the gate electrode material, providing adverse effects on the device characteristics. Also, even when the gate electrode is not prefabricated, the occurrence of leak current between the neighboring elements when the insulating film is filled in the gaps between the elements lead to instability in the operation of the device.

### SUMMARY

The present disclosure provides a semiconductor device that reduces adverse effects of metal ions remaining between the insulating film and the semiconductor substrate and dangling bonds to the possible extent even when a step is employed in which the trench is filled by laminating thin films such as ALD as described above to avoid occurrence of voids. The present disclosure is also directed to a method of manufacturing such semiconductor device.

A method of manufacturing a semiconductor device of the present disclosure includes forming a gate insulating film on a semiconductor substrate; forming a polycrystalline silicon film on the gate insulating film; forming a silicon nitride film on the polycrystalline silicon film; anisotropically etching the silicon nitride film, the polycrystalline silicon film, the gate insulating film and the semiconductor substrate so as to form a trench; forming a first silicon oxide film on a surface of the trench by thermal CVD process; forming a second silicon oxide film on the first silicon oxide film, the second silicon oxide film including a silicon oxide film (SiOx: x≦2) or a silicon oxide film containing 1×10¹³/cm³ or more metal atoms or carbon atoms; and executing plasma treatment on the second silicon oxide film in an oxidating atmosphere.

A semiconductor device of the present disclosure includes a semiconductor having a surface and a trench defined therein; a gate insulating film formed on the surface of the semiconductor substrate; a polycrystalline silicon film formed on the gate insulating film; a first silicon oxide film formed on a surface of the trench; and a second silicon oxide film formed on the first silicon oxide film, the second silicon oxide film including a silicon oxide film (SiOx: x≦2) or a silicon oxide film containing 1×10¹³/cm³ or more metal atoms or carbon atoms.

### BRIEF DESCRIPTION OF THE DRAWINGS

Other objects, features and advantages of the present disclosure will become clear upon reviewing the following description of the embodiment of the present disclosure with reference to the accompanying drawings, in which,

FIG. 1 is a schematic cross sectional view illustrating a first embodiment of the present disclosure;

FIG. 2 is a schematic cross sectional view showing one phase of a manufacturing step;

FIG. 3 is a schematic cross sectional view showing one phase of a manufacturing step (2^{nd} variation);

FIG. 4 is a schematic cross sectional view showing one phase of a manufacturing step (3^{rd} variation);

FIG. 5 is a schematic cross sectional view showing one phase of a manufacturing step (4^{th} variation);

FIG. 6 is a schematic cross sectional view showing one phase of a manufacturing step (5^{th} variation);

FIG. 7 is a schematic cross sectional view showing one phase of a manufacturing step (6^{th} variation);

FIG. 8 is a schematic cross sectional view indicating a second embodiment of the present disclosure;

FIG. 9 is a schematic cross sectional view showing one phase of a manufacturing step;

FIG. 10 is a schematic cross sectional view showing one phase of a manufacturing step (2^{nd} variation);

FIG. 11 is a schematic cross sectional view showing one phase of a manufacturing step (3^{rd} variation);

FIG. 12 is a schematic cross sectional view showing one phase of a manufacturing step (4^{th} variation);

FIG. 13 is a schematic cross sectional view showing one phase of a manufacturing step (5^{th} variation);

FIG. 14 is a schematic cross sectional view showing one phase of a manufacturing step (6^{th} variation);

FIG. 15 is a schematic cross sectional view showing one phase of a manufacturing step (7^{th} variation);

FIG. 16 is a schematically describing the principle of forming an Al-atomic layer and a SiOy film;

FIG. 17 is a schematic cross sectional view of a device for performing plasma oxidation;

FIG. 18 is a schematic cross sectional view indicating a third embodiment of the present disclosure;

FIG. 19 is a schematic cross sectional view showing one phase of a manufacturing step;

FIG. 20 is a schematic cross sectional view showing one phase of a manufacturing step (2^{nd} variation); and

FIG. 21 is a schematic cross sectional view showing one phase of a manufacturing step (3^{rd} variation).

### DETAILED DESCRIPTION

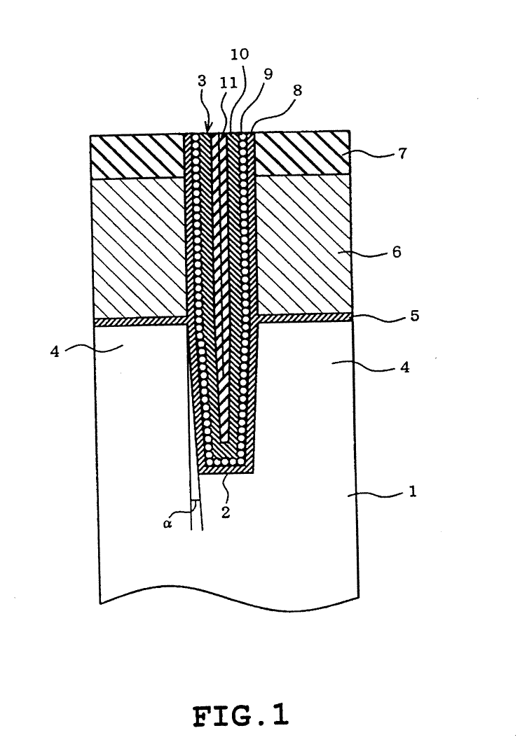

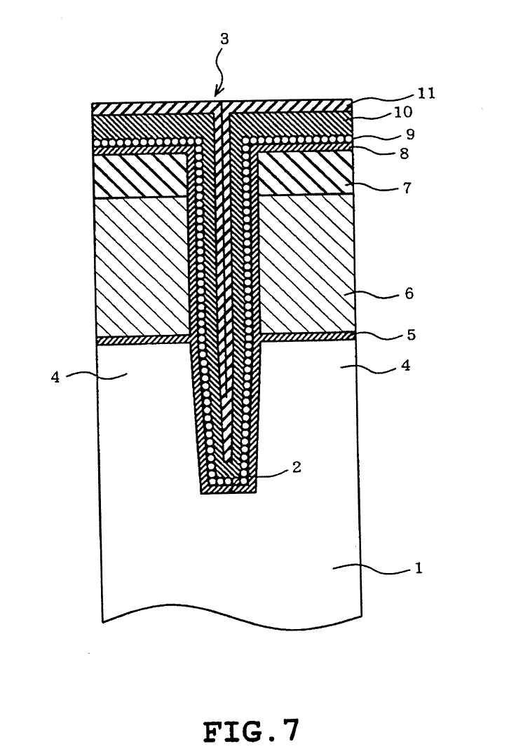

One embodiment of the present disclosure will be described with reference to FIGS. 1 to 7.

FIG. 1 is a schematic view of a cross section of a portion of an element isolation region being manufactured in case the present disclosure is applied to a semiconductor device such as a flash memory device.

A silicon substrate 1 serving as a semiconductor substrate has an STI (Shallow Trench Isolation) 3 formed therein which projects from the substrate surface and is composed of insulating film.

A gate oxide film 5 serving as a gate insulating film is formed on the surface of an active region 4 of the silicon substrate 1 and a polycrystalline silicon film 6 is formed on the upper surface of the gate oxide film 5. Further, a silicon nitride film 7 is laminated on the upper surface of the polycrystalline silicon 6. The silicon nitride film 7 functions as a stopper for CMP (Chemical Mechanical Polishing) process and is removed in a later step.

The STI 3 composed of insulating films is formed by laminating a plurality of insulating films in the inner surface of a trench 2. An HTO (High Temperature Oxide) film 8 composed of a silicon oxide film formed by thermal CVD (Chemical Vapor Deposition) is formed on a portion of the trench 2 contacting a surface of the silicon substrate 1 and a portion contacting the sidewalls of the gate oxide film 5, polycrystalline silicon film 6, and the silicon nitride film 7. The HTO film 8 has laminated thereon an Al atomic layer 9 formed by attachment of aluminum (Al) atoms on the surface of the HTO film 8 and a silicon-rich SiOy (y<2) film 10. The SiOy (y<2) film 10 similarly has a silicon-rich SiOy film 11 laminated thereon thus, filling the inner portion of the trench 2. A second oxide film is constituted by the Al atomic layer 9 and the SiOy film 10. The second oxide film contains aluminum atom, which is a metal atom, of 1×10¹³/cm³ or greater and the film thickness of one layer is formed at 100 nm or less.

Since the silicon-rich SiOy films 10 and 11 can be formed inside the trench 2 in forming STI 3 having high aspect ratio also without occurrence of voids, electrical insulation is secured, providing advantageous device characteristics. Also, in the above configuration, since the Al atomic layer 9 and the SiOy layer 10 are formed after forming the HTO film 8 on the inner surface of the trench 2, adverse effects on electrical characteristic imposed by Al atomic layer 9 can be prevented.

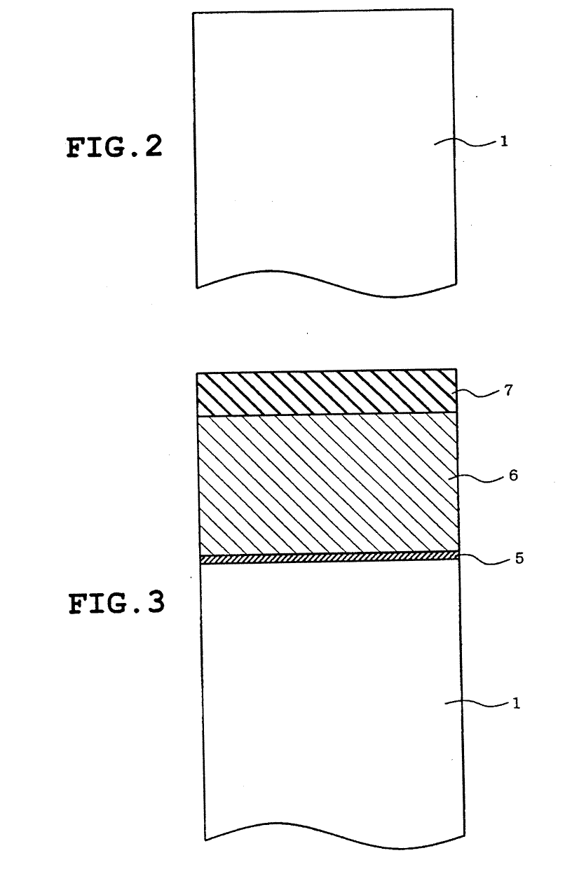

Next, a description on the manufacturing steps of the above configuration will be given based on FIGS. 2 to 7.

Referring to FIG. 3, first, the gate oxide film 5 is formed on the silicon substrate 1 illustrated in FIG. 2 serving as a semiconductor substrate whereafter the polycrystalline silicon film 6 and the silicon nitride film 7 are laminated. At this time, since the illustrated region indicates a transistor portion of the memory cell region, the gate oxide film 5 is configured at film thickness corresponding to the operation of the memory cell transistor. Also, the polycrystalline film 6 is formed to constitute a portion of the floating gate electrode. The silicon nitride film 7 functions as an etch mask and a CMP stopper as will be described afterwards.

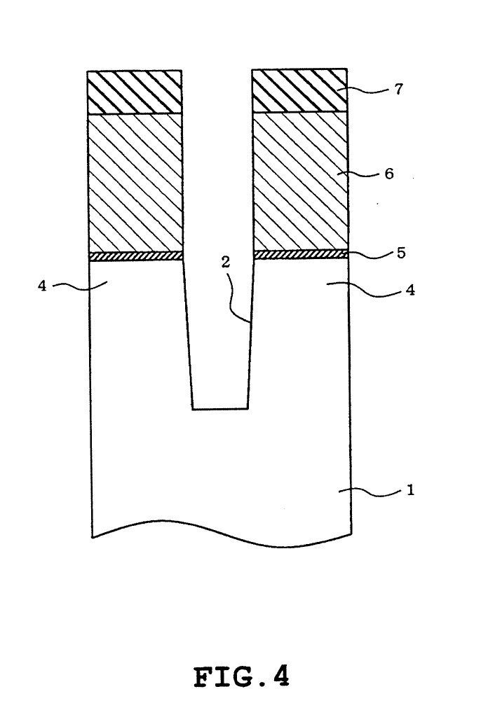

Subsequently, as shown in FIG. 4, resist is patterned by photolithography process on the silicon nitride film 7, and the silicon nitride film 7 is etched by RIE process using the patterned resist as a mask. Then, polycrystalline silicon film 6, the gate oxide film 5 and the silicon substrate 1 are etched to define the trench 2 in a predetermined depth. The trench 2 is formed to have a planar bottom surface and the sidewalls are slightly sloped to define an upward opening (a positive taper having a positive incline α from the vertical direction).

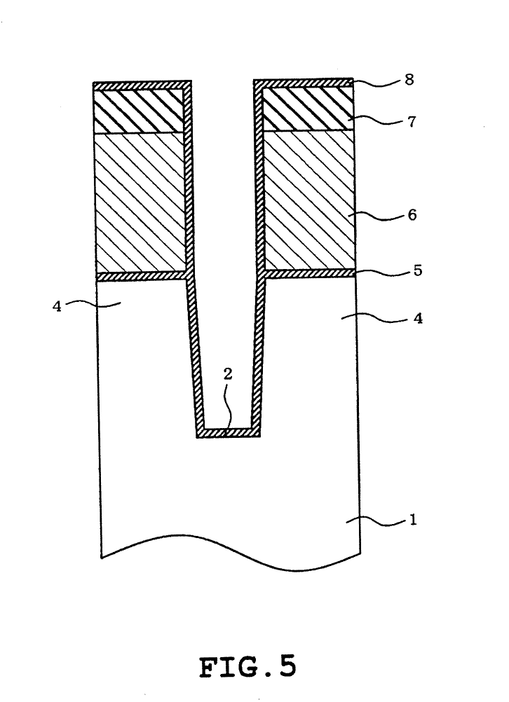

Next, as illustrated in FIG. 5, the HTO film 8 is formed on the inner wall surface of the trench 2. The HTO film 8 is formed by thermal CVD process using for example 50 to 150 sccm of dichlorosilane (SiH₂Cl₂) gas and 100 to 300 sccm of N₂O gas at processing temperature of 700 to 800° C. under pressure in the magnitude of 30 to 50 Pa. The HTO film 8 may be formed at thickness of 2.5 nm or greater, and in this case, is formed at 5 nm, for example. It has been verified that this film thickness obtains sufficient preventive effect against leak current.

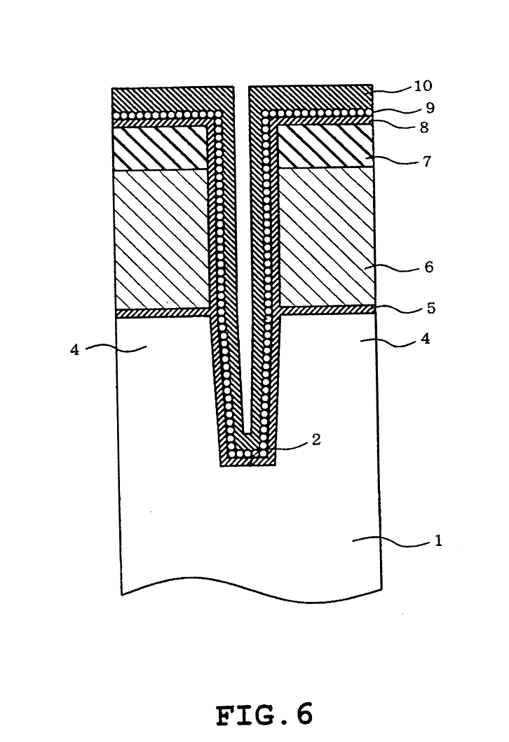

Subsequently, as shown in FIG. 6, the Al atomic layer 9 and the SiOy film 10 are formed on the HTO film 8. The Al atomic layer 9, for example, is formed by adsorbing aluminum on the surface of the HTO film 8 by flowing 10 to 300 sccm of TMA (Trimethylaluminum) gas for about 1 to 30 seconds in a vacuum chamber placed in Ar gas or He gas atmosphere at a temperature in the range of 200 to 450° C. and under pressure in the range of 20 to 100 Pa.

Thereafter, by flowing silanol based gas, for example (Si(OCH₃)₃OH) gas in the amount of 20 to 500 sccm in the above described atmosphere for about 2 to 60 seconds, Al—O—Si—(OCH₃)₃ bond is formed on the Al atomic layer 9, thereby forming a silicon-rich SiOy film 10. By repeating the above step, silicon-rich SiOy film 11 is laminated on SiOy film 10 to reliably fill the trench 2. The illustrated state shows the trench 2 being fully filled by the second fill. At this time, a single layer of Al atomic layer 9 and SiOy film 10 are configured at 100 nm or less, however the trench 2 may be filled by three or more repeated fills.

Thereafter, CMP process is carried out by using the silicon nitride film 7 as a stopper to obtain the STI 3 illustrated in FIG. 1. Then, by further digging down the insulating films forming the STI 3, or removing the silicon nitride film 7, the lower layer portion of the floating gate electrode can be formed.

Then, by further laminating multiple layers of gate electrode material on the underlying configuration, the floating gate electrode, the gate insulating film, and the control gate electrode are formed whereafter conductive material is patterned to obtain a flash memory device.

Thus, since the HTO film 8, the Al atomic layer 9 and the silicon-rich SiOy films 10 and 11 are laminated inside the trench 2 to form the STI 3, the trench 2 can be filled without voids. Moreover, since the HTO film 8 is initially formed in the trench 2, leak current caused by the Al atomic layer 9 can be eliminated, thereby providing favorable electrical characteristics.

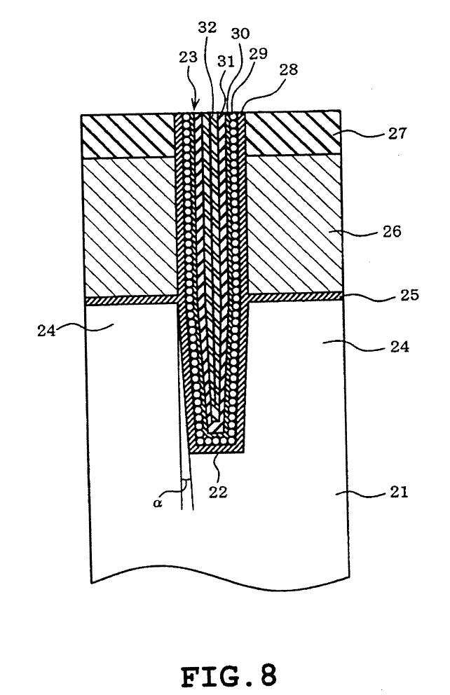

A description will be given on a second embodiment of the present disclosure with reference to FIGS. 8 to 17.

FIG. 8 illustrates an element isolation region applied to a semiconductor device such as flash memory device. More specifically, FIG. 8 illustrates a schematic cross section of the element isolation region undergoing the manufacturing steps. The illustrated portion shows the configuration of the portion in which the transistors in the memory cell region of flash memory are isolated.

An STI (Shallow Trench Isolation) 23 composed of insulating films is defined on the surface of a silicon substrate 21 serving a semiconductor substrate so as to project from the substrate surface. Active regions 24 are formed on the silicon substrate 21 surface by isolation of the STI 23.

A gate oxide film 25 serving as a gate insulating film is formed on the surface of the active region 24 of the silicon substrate 21 and a polycrystalline silicon film 26 is laminated on the upper surface of the gate oxide film 25. Further, a silicon nitride film 27 is laminated on the upper surface of the polycrystalline silicon film 26. The silicon nitride film 27 functions as a stopper for CMP (Chemical Mechanical Polishing) process and is removed in the later step.

The STI 23 composed of insulating films is formed by laminating a plurality of films on the inner surface of a trench 22. An HTO (High Temperature Oxide) film 28 composed of a silicon oxide film formed by thermal CVD (Chemical Vapor Deposition) is formed on a portion of the trench 22 contacting the surface of the silicon substrate 21 and a portion contacting the sidewalls of a gate oxide film 25, polycrystalline silicon film 26, and the silicon nitride film 27 in the thickness of 5 nm for example. The HTO film 28 is formed as a first oxide film and has laminated thereon an Al atomic layer 29 formed by attachment of aluminum (Al) atoms on the surface of the HTO film 28 and a silicon-rich SiOy (y<2) film 30. A single layer of Al atomic layer 29 and SiOy film 30 are configured at 100 nm or less.

The silicon-rich SiOy film 30 is provided as the second oxide film along with the Al atomic layer 29, and the upper layer side of the silicon-rich SiOy (y<2) film 30 is constituted by a silicon oxide SiOx (x>y) film 31 with increased content ratio of oxygen due to plasma oxidation. A similarly silicon-rich SiOy film 32 is further laminated on the surface of the silicon oxide film SiOx (x>y) film 31, thus filling the trench 22.

The silicon-rich SiOy films 30 and 32 can be formed inside the trench 22 without voids even in forming STI 23 having high aspect ratio. Thus, electrical insulation can be secured reliably to obtain advantageous electrical characteristics. Also, in the above configuration, since the Al atomic layer 29 and SiOy film 30 are formed after forming HTO film 28 on the inner surface of the trench 2, adverse effects imposed on electrical characteristics by the by the Al atomic layer 29 can be prevented.

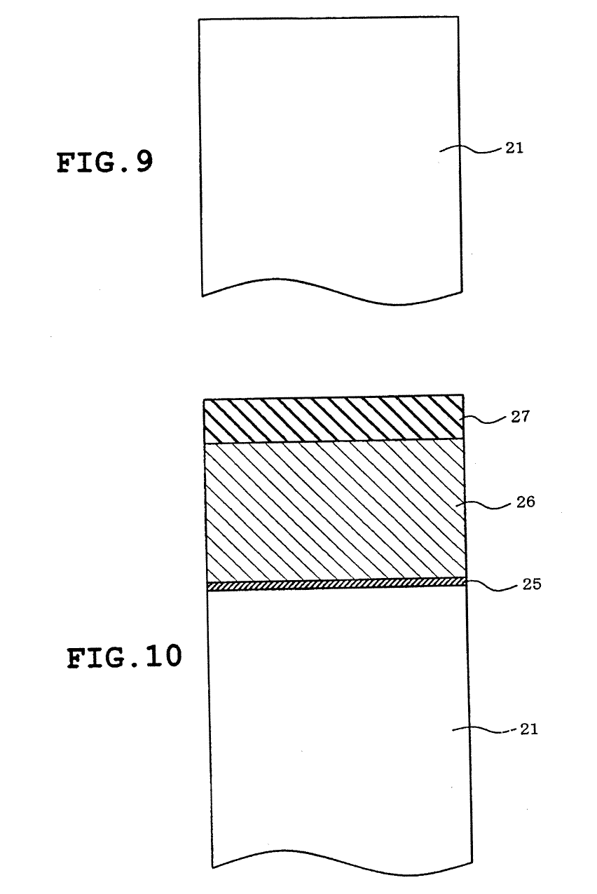

Next, the manufacturing steps of the above configuration will be described with reference to FIGS. 9 to 17.

Referring to FIG. 10, first, the gate oxide film 25 is formed on a silicon substrate 21 illustrated in FIG. 9 serving as a semiconductor substrate whereafter the polycrystalline silicon film 26 and silicon nitride film 27 are laminated. At this time, since the illustrated region indicates a transistor portion of the memory cell region, the gate oxide film 25 is configured at film thickness corresponding to the operation of the memory cell transistor. Also, the polycrystalline film 26 is formed to constitute a portion of the floating gate electrode since the transistors are formed by prefabricating the gate. The silicon nitride film 7 functions as an etch mask and CMP stopper as will be described afterwards.

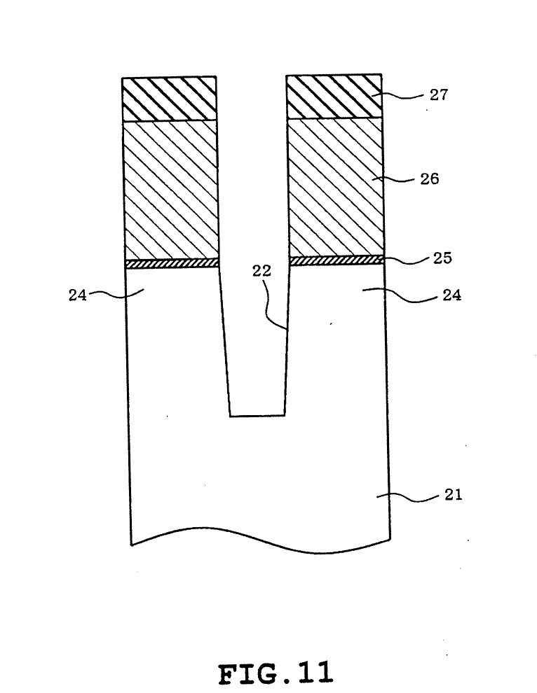

Subsequently, as shown in FIG. 11, resist is patterned by photolithography process on the silicon nitride film 27, and the silicon nitride film 27 is etched by RIE process using the patterned resist as a mask. Then, polycrystalline silicon film 26, the gate oxide film 25 and the silicon substrate 21 are etched to define the trench 22 in a predetermined depth. The trench 22 is formed to have a planar bottom surface and the sidewalls are slightly sloped to define an upward opening (a positive taper having a positive incline α from the vertical direction).

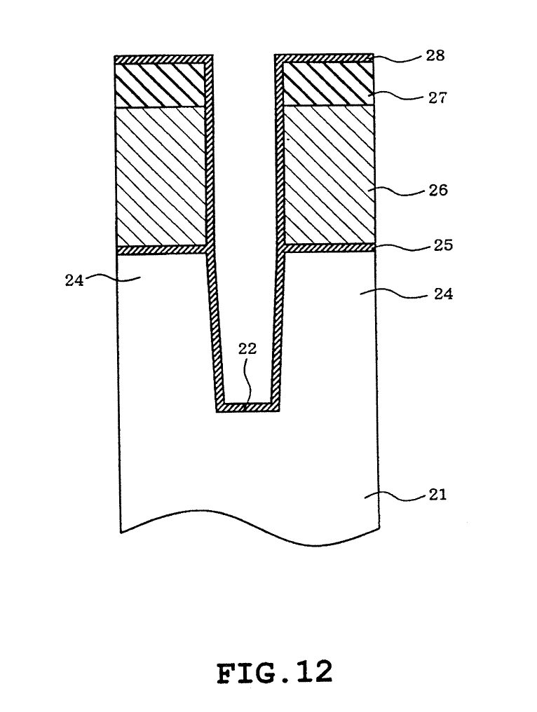

Next, as illustrated in FIG. 12, the HTO film 28 is formed on the inner wall surface of the trench 22. The HTO film 28 is formed by thermal CVD process using for example 50 to 150 sccm of dichlorosilane (SiH₂Cl₂) gas and 100 to 300 sccm of N₂O gas at processing temperature of 700 to 800° C. under a pressure in the magnitude of 30 to 50 Pa. The HTO film 28 may be formed at thickness of 2.5 nm or greater, and in this case, is formed at 5 nm, for example.

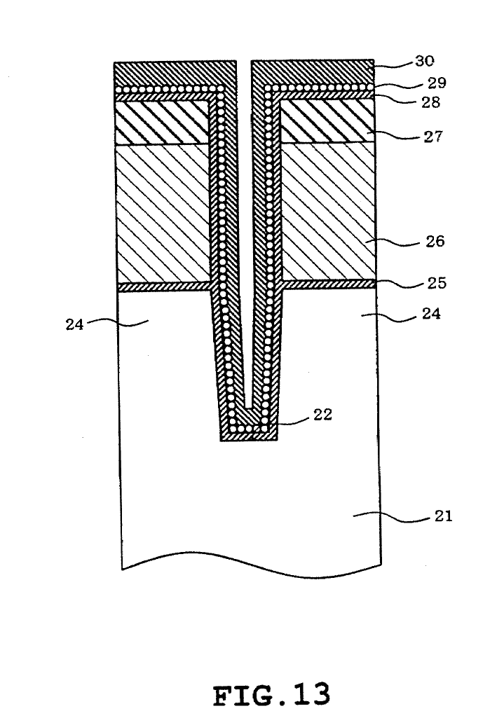

Subsequently, as shown in FIG. 13, Al atomic layer 29 and SiOy film 30 are formed on the HTO film 28. The Al atomic layer 29, for example, is formed by adsorbing aluminum on the surface of the HTO film 28 by flowing 10 to 300 sccm of TMA (Trimethylaluminum) gas for about 1 to 30 seconds in a vacuum chamber placed in Ar gas or He gas atmosphere at a temperature in the range of 200 to 450° C. and under pressure in the range of 20 to 100 Pa.

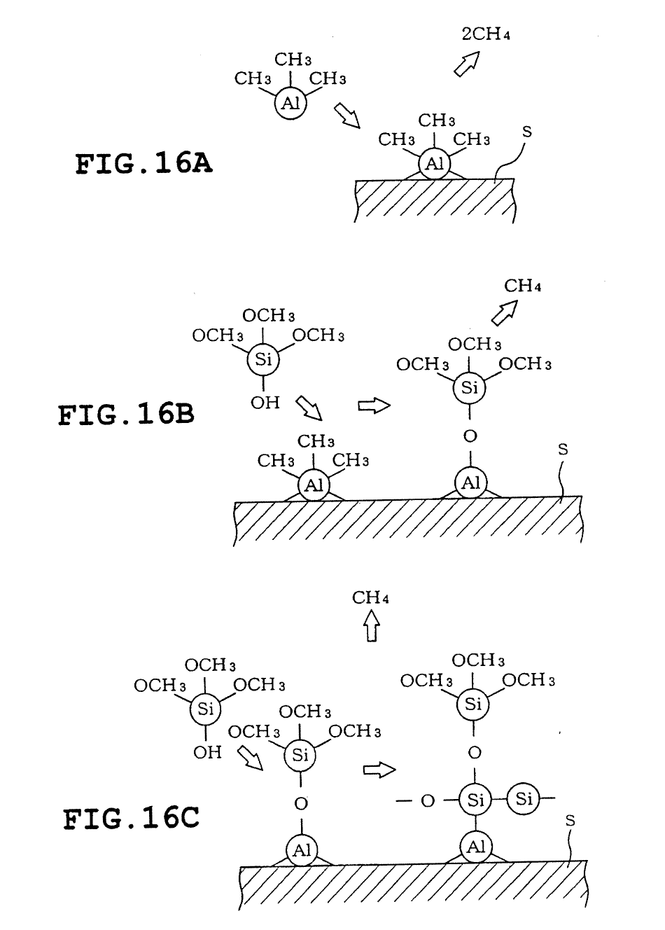

As illustrated in FIG. 16A, TMA gas is flown onto an underlying substrate S. When the TMA molecule reaches the substrate S surface, a reaction occurs where Al atom is adsorbed, whereby Al atom binds with the substrate S surface via oxygen atom constituting a single layer of aligned Al atoms. Thus, Al atomic layer 29 is formed. Each Al atom forming the Al atomic layer 29 has methyl group CH₃ remaining thereto.

Thereafter, by flowing silanol based gas, for example Si(OCH₃)₃OH gas in the amount of 20 to 500 sccm in the above described atmosphere for about 2 to 60 seconds, Al—O—Si—(OCH₃)₃ bond is formed on the Al atomic layer 9, thereby forming a silicon-rich SiOy film 30.

As illustrated in FIG. 16B, when silanol based gas approaches the substrate S surface, the OH group of the silanol molecule reacts with the methyl group CH₃ binding with the Al atom of the Al atomic layer 29 and binds with the methyl group CH₃ via oxygen atom. At this time, methane gas CH4 is generated by the binding reaction. Such reaction is repeated thereafter to form a silicon-rich SiOy film 30 as illustrated in FIG. 16C,

In this case, the second oxide film is constituted by the Al atomic layer 29 and the SiOy layer 30 and the second oxide film contains aluminum atom, which is a metal atom, of 1×10¹³/cm³ or greater and the film thickness of one layer is formed at 100 nm or less.

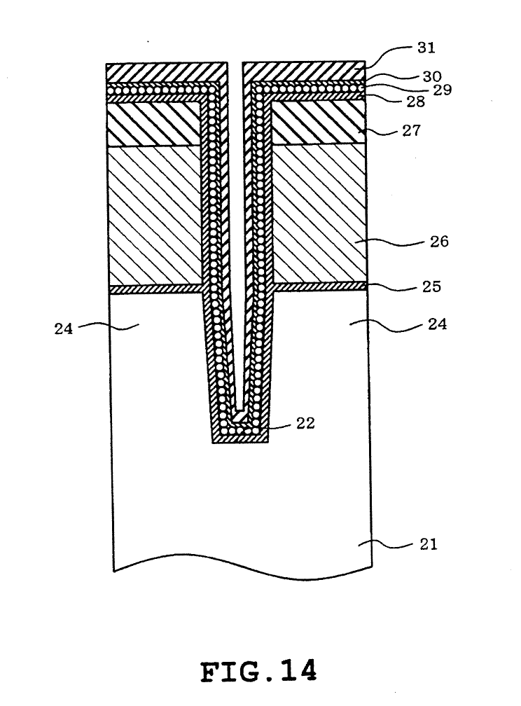

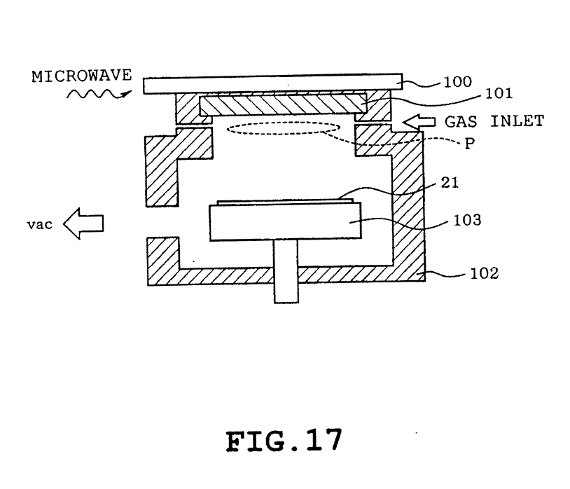

Next, as illustrated in FIG. 14, an insulating film 31 is formed by radical oxidation. The insulating film 31 formed by radical oxide is formed by carrying the silicon substrate 21 being processed on to a stage 103 of a vacuum chamber 102 provided with a conductive wave tube 100 and a quartz window 101 illustrated in FIG. 17 (the aforementioned chamber may be used). Then, approximately 50 sccm of O₂ (oxygen) gas is flown under 50 Pa of pressure to generate a surface wave plasma P. The radical oxidation converts the SiOy (y<2) film 30 to SiOx (x<y≦2) film to form an oxide film with reduced amount of silicon on a portion of the surface side.

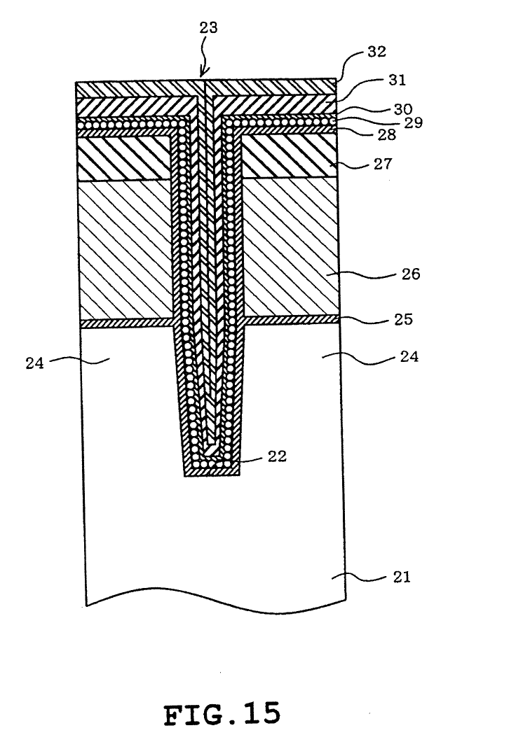

Thus, the SiOy film 30 reliably fills the trench 2 with very low occurrence of voids and moreover stabilizes insulation characteristics in terms of electrical characteristics by oxidating the upper layer portion of the SiOy film 30 by radical oxidation so as to reduce the amount of silicon. In the present embodiment, after forming SiOx film 31, a silicon-rich SiOx film 32 is formed repeatedly by the same method taken in forming the SiOy film 30, thereby completing the filling of the trench 22 as illustrated in FIG. 15.

As describe above, since HTO film 28, Al atomic layer 29, and silicon-rich SiOy films 30 and 32, and SiOx film 31 are laminated to form the STI 23, the trench 22 can be reliably filled without occurrence of voids. Moreover, since HTO film 28 is formed initially in the trench 22, leak current caused by Al atomic layer 29 can be eliminated to provide favorable electrical characteristics.

Thereafter, CMP process is carried out by using silicon nitride 27 as a stopper to form the STI 23 as illustrated in FIG. 8. Then, by further digging down the insulating films forming the STI 23, or removing the silicon nitride film 27, lower layer portion of the floating gate electrode can be formed. Then, by further stacking multiple layers of gate electrode material on the underlying configuration, the floating gate electrode, the gate insulating film, and the control gate electrode are formed whereafter conductive material is patterned to obtain a flash memory device.

By forming the flash memory device as described above, the trench 22 can be filled reliably by the insulating films, thus providing improved element isolation characteristics and stabilized electrical characteristics, consequently allowing improvement in yield rate.

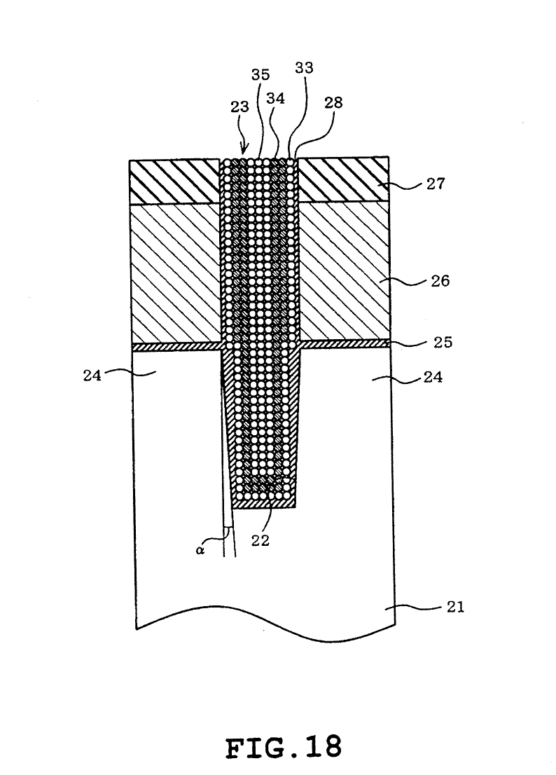

FIGS. 18 to 21 illustrate a third embodiment of the present disclosure. A description will be given hereunder on portions that differ from the second embodiment. FIG. 18 shows a configuration similar to the second embodiment, in which the STI (Shallow Trench Isolation) 23 composed of insulating films is defined on the surface of the silicon substrate 21 serving a semiconductor substrate so as to project from the substrate surface. Active regions 24 are formed on the silicon substrate 21 surface by isolation of the STI 23. The gate oxide film 25 serving as a gate insulating film is formed on the surface of the active region 24 of the silicon substrate 21 and the polycrystalline silicon film 26 is laminated on the upper surface of the gate oxide film 25. Further, the silicon nitride film 27 is laminated on the upper surface of the polycrystalline silicon film 26.

The STI 23 composed of insulating films is formed by laminating a plurality of films on the inner surface of the trench 22. The HTO (High Temperature Oxide) film 28 composed of a silicon oxide film formed by thermal CVD (Chemical Vapor Deposition) is formed on the portion of the trench 22 contacting the surface of the silicon substrate 21 and the portion contacting the sidewalls of the gate oxide film 25, polycrystalline silicon film 26, and the silicon nitride film 27 in the thickness of 5 nm for example. The HTO film 28 is formed as the first oxide film and has laminated on the surface thereof a silicon-rich SiOy (y<2) film 33 serving as a second oxide film formed by the later described method.

The upper layer side of the silicon-rich SiOy (y<2) film 33 is constituted by a silicon oxide film SiOx (x>y) film 34 with increased content ratio of oxygen due to plasma oxidation. A similarly silicon-rich SiOy film 35 is further laminated on the surface of the silicon oxide film SiOx (x>y) film 34, thus filling the trench 22.

The silicon-rich SiOy films 33 and 35 can be formed inside the trench 22 without voids even in forming STI 23 having high aspect ratio. Thus, electrical insulation can be secured reliably to obtain advantageous electrical characteristics. Also, in the above configuration, since the SiOy film 33 is formed after forming HTO film 28 on the inner surface of the trench 22, thus, adverse effects imposed on electrical characteristics by the silicon rich state can be prevented.

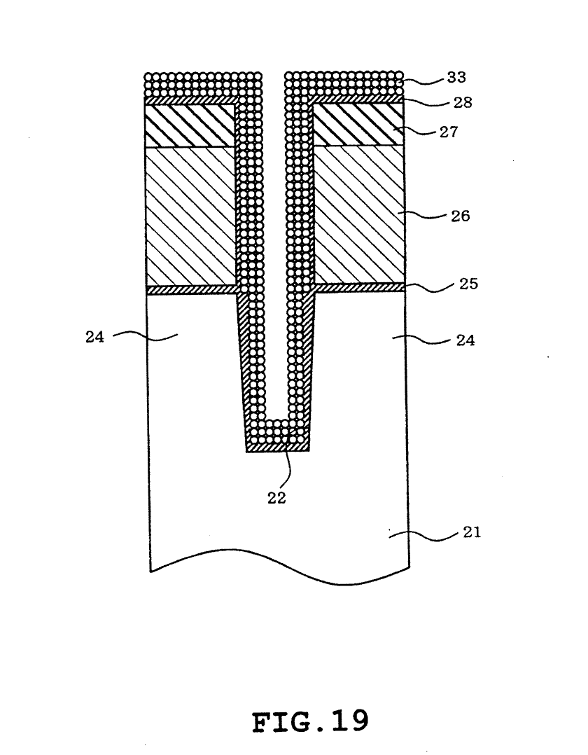

Next, the manufacturing steps of the above configuration will be described with reference to FIGS. 19 to 21 also.

The steps illustrated in FIGS. 9 to 12 are carried out on the silicon substrate 21 as described in the second embodiment. That is, the gate oxide film 25, the polycrystalline silicon film 26, and the silicon nitride film 27 are laminated sequentially. Thereafter, the silicon nitride film 27, the polycrystalline silicon film 26, the gate oxide film 25 and the silicon substrate 21 are etched sequentially to form the trench 22. The trench 22 is formed to have a planar bottom surface and the sidewalls are slightly sloped to define an upward opening (a positive taper having a positive incline α from the vertical direction).

Next the HTO film 28 is formed on the inner wall surface of the trench 22 by thermal CVD process using for example 50 to 150 sccm of dichlorosilane (SiH₂Cl₂) gas and 100 to 300 sccm of N₂O gas at processing temperature of 700 to 800° C. under a pressure in the magnitude of 30 to 50 Pa. The HTO film 28 may be formed at thickness of 2.5 nm or greater, and in this case, is formed at 5 nm, for example.

Subsequently, as shown in FIG. 19, the SiOy film 33 is formed on the HTO film 28. The SiOy film 33 is formed as follows. The silicon substrate 21 is placed in a vacuum chamber and under an atmosphere where inactive gas such as Ar (argon) gas or He (helium) gas is flown at a temperature ranging from 200 to 550° C. under pressure ranging from 20 to 150 Pa and O₃ (ozone) gas is flown for 1 to 3 seconds in the amount of 20 to 400 sccm. Next, 15 to 300 sccm of TDEAS (tetradiethylamidsilicon) gas is flown for 1 to 3 seconds. At this time, total amount of TDEAS gas flown is specified at twice the amount of total amount of O₃ gas or greater. Thus, SiOy (y<2)) film 33 is deposited in the thickness of about 5 nm.

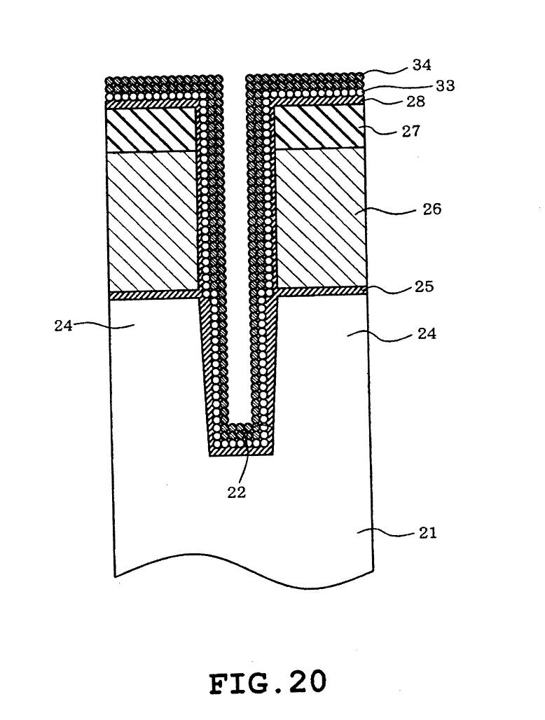

Next, referring to FIG. 20, an insulating film 34 is formed by radical oxidation. The insulating film 34 formed by radical oxide is formed by carrying the silicon substrate 21 being processed on to a stage 103 of a vacuum chamber 102 provided with a conductive wave tube 100 and a quartz window 101 illustrated in FIG. 17 (the aforementioned chamber may be used). Then, approximately 50 sccm of O₂ (oxygen) gas is flown under 50 Pa of pressure to generate a surface wave plasma P. The radical oxidation converts the SiOy (y<2) film 33 to SiOx (x<y≦2) film to form an oxide film with reduced amount of silicon on a portion of the surface side.

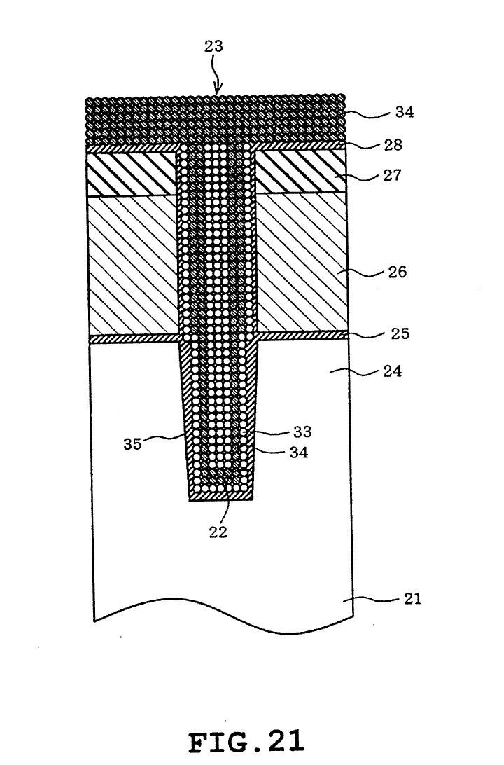

By repeating the formation of SiOy film 33 and SiOx film 34 twice, filling of the trench 22 is completed as illustrated in FIG. 21.

As described above, since the STI 23 is formed by laminating the HTO film 28, the silicon-rich SiOy film 33, and SiOx film 34 inside the trench 22, the trench 22 can be filled reliably without voids. Moreover, since the HTO film 28 is formed initially in the trench 22, leak current caused by Al atomic layer 29 can be eliminated, thereby providing favorable electrical characteristics. Then, by carrying out CMP process by using silicon nitride film 27 as a stopper, the STI 23 can be formed as illustrated in FIG. 18.

Flash memory formed as described above, allows the trench 22 to be filled reliably with insulating films, whereby element isolation characteristics is improved and electrical characteristics is stabilized, consequently improving the yield rate.

The present embodiment is not limited to the above described embodiments but may be modified or expanded as follows.

In stead of dichlorosilane (SiH₂Cl₂) gas used in forming the HTO film 8 and 28 in the above embodiment, silane (SiH₄) may be used. At this time, the HTO films 8 and 28 can be formed if the following conditions are applied: temperature at 750 to 850° C., pressure at 65 Pa to 133 Pa, amount of SiH₄ gas 20 to 40 sccm, and amount of N₂O gas 1500 to 2000 sccm.

The HTO films 8 and 28 can be of any thickness if 2.5 nm or greater, and is not limited to 5 nm described in the embodiments.

Instead of O₂ gas used for plasma oxidation in the above described embodiment; O₃ (ozone) gas, H₂O₂ (hydrogen peroxide) vapor may be used.

In forming the trenches 2 and 22 in the silicon substrates 1 and 21, the incline α (taper angle) has been configured so that the width of the trenches 2 and 22 become narrower in proportion to the proximity to the trench bottom by RIE process; however the incline can be configured to the appropriate angle if equal to zero or greater.

(Si(OCH₃)₃OH) gas has been used in forming SiOy films 10, 30, and 33 with silanole based gas in the above embodiment; however, other types of silanole based gas such as Si (OCₓ₁H_{y1})(OCₓ₂H_{y2})(OCₓ₃H_{y3})OH (x1, x2, x3=1 to 10, y1=2×x1+1, y2=2×x2+1, y3=2×x3+1).

TMA has been used in forming Al atomic layers 9 and 29 in the above described embodiment; however, DMAH (dimethylaluminumhydride) (Al(CH₃)₂H), TEA (tetraethylaluminium) (Al(CH₃)₄) or TMAH (diethylaluminumhydride) (Al(C₂H₅)₂H) may be used.

The above described embodiment discloses an example of providing Al atomic layers 9 and 29, however, metals such as Cu (copper), Ag (silver), Ti (titanium) and Nb (niobium) or C (carbon) may be used instead; or the combination of the above may be used instead.

The above described embodiment discloses an example of using TDEAS (tetradiethylamidsilicon) gas as an organic compound however either of TDMS (tetradimethylaminosilicon), TEMAS (tetraethylmethylaminosilicon) and HSi (N(CH₃)(C₂H₅))₃ may be used instead.

The present disclosure has been described by application to flash memory device; however, the present invention may be applied to semiconductor device such as MRAM and to semiconductor devices in general having trenches with high aspect ratio defined in the semiconductor substrate which are filled with insulating films.

The above described embodiment discloses an example of forming the first oxide film and the second oxide film with the polycrystalline silicon films 6 and 26 provided as a portion of the gate electrode. However, trenches may be formed defined in a state where silicon nitride film is formed directly on the gate insulating film without polycrystalline silicon film.

The foregoing description and drawings are merely illustrative of the principles of the present disclosure and are not to be construed in a limited sense. Various changes and modifications will become apparent to those of ordinary skill in the art. All such changes and modifications are seen to fall within the scope of the disclosure as defined by the appended claims.

What is claimed is:

1. A method of manufacturing a semiconductor device, comprising:
forming a gate insulating film on a semiconductor substrate;
forming a polycrystalline silicon film on the gate insulating film;
forming a silicon nitride film on the polycrystalline silicon film;
anisotropically etching the silicon nitride film, the polycrystalline silicon film, the gate insulating film and the semiconductor substrate so as to form a trench;
forming a first silicon oxide film on a surface of the trench by thermal CVD process;
forming a second silicon oxide film on the first silicon oxide film, the second silicon oxide film including a silicon oxide film (SiOx: x≦2) or a silicon oxide film containing 1×10¹³/cm³ or more metal atoms or carbon atoms; and
executing plasma treatment on the second silicon oxide film in an oxidating atmosphere.

2. A method of manufacturing a semiconductor device, comprising:
forming a gate insulating film on a semiconductor substrate;
forming a silicon nitride film on the gate insulating film;
anisotropically etching the silicon nitride film, and the gate insulating film and the semiconductor substrate so as to form a trench;
forming a first silicon oxide film on a surface of the trench by thermal CVD process;
forming a second silicon oxide film on the first silicon oxide film, the second silicon oxide film including a silicon oxide film (SiOx: x≦2) or a silicon oxide film containing 1×10¹³/cm³ or more metal atoms or carbon atoms; and
executing plasma treatment on the second silicon oxide film in an oxidating atmosphere.

3. The method of claim 1, wherein the second silicon oxide film forming step and the plasma treatment executing step are repeated a plurality of times to fill the trench.

4. The method of claim 2, wherein the second silicon oxide film forming step and the plasma treatment executing step are repeated a plurality of times to fill the trench.

5. The method of claim 1, wherein the second silicon oxide film forming step includes exposing the semiconductor substrate to a vacuum atmosphere having organic compound containing Al (aluminum), and exposing the semiconductor substrate to a vacuum atmosphere having organic compound containing silicon.

6. The method of claim 2, wherein the second silicon oxide film forming step includes exposing the semiconductor substrate to a vacuum atmosphere having organic compound containing Al (aluminum), and exposing the semiconductor substrate to a vacuum atmosphere having organic compound containing silicon.

7. The method of claim 1, wherein the second silicon oxide film forming step includes exposing the semiconductor substrate to a vacuum atmosphere having organic compound containing silicon, and exposing the semiconductor substrate to a vacuum atmosphere containing oxidating gas.

8. The method of claim 2, wherein the second silicon oxide film forming step includes exposing the semiconductor substrate to a vacuum atmosphere having organic compound containing silicon, and exposing the semiconductor substrate to a vacuum atmosphere containing oxidating gas.

9. A semiconductor device, comprising:
a semiconductor having a surface and a trench defined therein;
a gate insulating film formed on the surface of the semiconductor substrate;
a polycrystalline silicon film formed on the gate insulating film;
a first silicon oxide film formed on a surface of the trench; and
a second silicon oxide film formed on the first silicon oxide film, the second silicon oxide film including a silicon oxide film (SiOx: x≦2) or a silicon oxide film containing 1×10¹³/cm³ or more metal atoms or carbon atoms.
